(19) United States
(12) Patent Application Publication
(10) Pub. No.: US 2006/0027323 A1
(43) Pub. Date: Feb. 9, 2006

(54) Substrate processing apparatus which performs predetermined processing by supplying a processing liquid to a substrate which is held at a substrate processing position

(75) Inventors: Katsuhiko Miya, Kyoto (JP); Koji Ando, Kyoto (JP)

Correspondence Address: OSTROLENK FABER GERB & SOFFEN, 1180 AVENUE OF THE AMERICAS, NEW YORK, NY, 100368403, US

(73) Assignee: Dainippon Screen Mfg. Co., Ltd.

(21) Appl. No.: 11/177,697

(22) Filed: Jul. 8, 2005

(30) Foreign Application Priority Data
Aug. 5, 2004 (JP) 2004-228866

(51) Int. Cl. H01L 21/306

(52) U.S. Cl. 156/345.23

(57) ABSTRACT

A top rim portion of a spin base 21 seats plural chuck pins F1 through F3 and S1 through S3 which are structured to abut on an outer circumferential surface of a substrate W and hold the substrate W, and further, plural support members 22 are fixed projecting upward on the top rim portion of the spin base 21 such that the plural support members 22 can abut on a bottom rim portion of the substrate W and support the substrate W. The chuck pins F1 through F3 and S1 through S3 comprise movable main members 231, which are axially supported at the spin base 21 so that the movable main members 231 can freely revolve, and abutting members 232 which are fixedly supported on the movable main members 231. As the movable main members 231 revolve, the abutting members 232 abut on and move away from the outer circumferential surface of the substrate W. The movable main members 231 are disposed on the outer side along the diameter direction of the substrate W relative to an opposed region FR where the spin base 21 is opposed against the substrate W.

### CROSS REFERENCE TO RELATED APPLICATION

The disclosure of Japanese Patent Application No. 2004-228866 filed Aug. 5, 2004 including specification, drawings and claims is incorporated herein by reference in its entirety.

### BACKGROUND OF THE INVENTION

1. Field of the Invention

The present invention relates to a substrate processing apparatus which performs processing, such as cleaning, of substrates of various types such as semiconductor wafers, glass substrates for photomask, glass substrates for liquid crystal display, glass substrates for plasma display and optical disk substrates while supplying a processing liquid to these substrates.

2. Description of the Related Art

Known as a substrate processing apparatus of this type is for instance a substrate processing apparatus in which a spin chuck rotating about a vertical axis holds a substrate such as a semiconductor wafer horizontally, a processing liquid such as an etching liquid and a rinsing liquid is supplied to the top and the bottom surfaces of the substrate, and the substrate is subjected to predetermined processing. In the substrate processing apparatus described in Japanese Patent Application Laid-Open Gazette No. 2004-111902 for instance, a spin chuck comprises a disk-shaped spin base (base member) which seats a substrate, and plural (six for example) firm holding members (substrate holders) such as chuck pins are disposed in a top rim portion of the spin base so that the firm holding members can freely revolve along a vertical axis. In other words, the top rim portion of the spin base has through holes which accept the firm holding members in such a manner that the firm holding members can freely revolve. Within a wedge-shaped plate-like portion which is fixed to the top end of a shaft (movable main member) which is disposed penetrating a top plate of the spin base and which can freely revolve along a vertical axis, a abutting portion (abutting member) is disposed upright and opposed against a circumferential edge surface of a substrate at positions off from a revolution shaft line of the shaft, thereby forming the respective firm holding members. Further, a support portion (substrate support) is disposed at a position corresponding to a position which is within the bottom surface of the substrate and inward by an extremely short distance from a rim portion, protruding at the center of revolutions of the plate-like portion. Hence, as the support portion supports the substrate from below at the rim portion of the bottom surface of the substrate, the shaft revolves and the abutting portion abuts on the circumferential edge surface of the substrate, the respective firm holding members firmly hold the substrate. In the conventional apparatus, each chuck pin is thus equipped with a substrate supporting function of supporting a substrate from the bottom surface side and a substrate holding function of holding a substrate at the outer circumferential edge.

### SUMMARY OF THE INVENTION

By the way, in the conventional apparatus, since the support portion which supports a substrate from below at the rim portion within the bottom surface of the substrate is disposed on the revolution shaft line of the shaft, the bottom surface of the substrate has a boundary portion (hereinafter referred to as the “movable portion”) between the shaft and the spin base (a through hole which is formed in the top plate of the spin base to accept the shaft such that the shaft can freely move). For the shaft to revolve, this movable portion inevitably has a clearance, and if a splashed processing liquid gets into this portion, the intruder processing liquid owing to the capillary phenomenon will spread across the clearance between the shaft and the through hole and create a pool of the processing liquid. The processing liquid thus entered the movable portion located below the bottom surface of the substrate will adhere to the bottom surface of the substrate as vapor during drying or other processing with the processing liquid or the like of the substrate and hence impair the uniformity of processing such as etching. Particularly where a substrate is positioned with its non-processing surface (namely, a device-seating surface on which a device is formed) directed to below and opposed against the top surface of the spin base over a short distance, the processing liquid entering the movable portion is more influential and could cause etching of the non-processing surface. While prevention of this inconvenience requires rinsing which will wash away the processing liquid which has entered the movable portion located below the bottom surface of the substrate, this will result in another problem that rinsing will take long time. Further, the existence of the movable portion within the bottom surface of the substrate subjects the bottom surface of the substrate to particles created by sliding of the shaft against the spin base.

The present invention has been made in light of the problems above. Accordingly, a primary object of the invention is to provide a substrate processing apparatus which prevents the inconveniences which occur when a processing liquid supplied to a substrate enters a movable portion of a substrate holder which holds the substrate.

The substrate processing apparatus according to the invention is a substrate processing apparatus which performs predetermined processing by supplying a processing liquid to a substrate which is held at a substrate processing position, comprising: plural substrate holders each of which includes an abutting member which is capable of abutting on an outer circumferential surface of the substrate, and which hold the substrate by contacting the abutting members with the outer circumferential surface of the substrate at the substrate processing position; and a base member which seats the plural substrate holders, wherein at least one of the plural substrate holders are movable substrate holders, and the movable substrate holders comprise movable main members which are structured to freely move relative to the base member with supporting the abutting members, and a drive mechanism which drives the movable main members and accordingly makes the abutting members abut on and move away from the outer circumferential surface of the substrate, and the movable main members are disposed on the outer side along the diameter direction of the substrate relative to an opposed region where the base member is opposed against the substrate.

In this structure according to the invention, at least one of the plural substrate holders is a movable substrate holder, and when the drive mechanism drives the movable main members, the abutting members abut on the outer circumferential surface of the substrate and hold the substrate. The processing liquid is supplied to the substrate thus held by the substrate holders, and the substrate is subjected to predetermined processing. Since the movable main members are disposed on the outer side along the diameter direction of the substrate relative to the opposed region where the base member is opposed against the substrate, even despite entry of the processing liquid such as a chemical solution to a boundary portion (movable portion) between the movable main members and the base member, it is possible to prevent the processing liquid thus entered the movable portion from adhering as vapor to the substrate while the substrate is dried or processed with the processing liquid, etc. Particularly during processing with the non-processing surface opposed against the base member, it is possible to prevent the processing liquid thus entered the movable portion from adhering as vapor to a non-processing surface of the substrate and avoid corrosion of the non-processing surface. This ensures uniform processing such as etching with the processing liquid. In addition, since the movable main members are located on the outer side along the diameter direction of the substrate relative to the opposed region where the base member is opposed against the substrate, even when particles are created as the movable main members slide against the base member, it is possible to reduce adhesion of the particles to the substrate.

The above and further objects and novel features of the invention will more fully appear from the following detailed description when the same is read in connection with the accompanying drawing. It is to be expressly understood, however, that the drawing is for purpose of illustration only and is not intended as a definition of the limits of the invention.

### BRIEF DESCRIPTION OF THE DRAWINGS

FIG. 1 is a drawing which shows the overall structure of the substrate processing apparatus according to a first embodiment of the invention;

FIG. 2 is a plan view of a spin chuck disposed to the substrate processing apparatus which is shown in FIG. 1;

FIG. 3 is a plan view for describing the arrangement of operation translation mechanisms which are disposed inside a spin base of the spin chuck;

FIG. 4 is a cross sectional view for describing the structure relevant to the spin chuck;

FIG. 5 is a plan view for describing the structure of a drive mechanism which drives the spin chuck;

FIG. 6 is a plan view for describing the structure of a first and a second non rotation-side movable members which the drive mechanisms drive;

FIG. 7 is a perspective view for describing the structure of the operation translation mechanism which is for translating drive force transmitted from the first and the second non rotation-side movable members into an operation of chuck pins;

FIG. 8 is a partial cross sectional view of the structure of the chuck pins;

FIG. 9 is a perspective view for describing the structure of the other section of the operation translation mechanism;

FIG. 10 is a drawing which shows the overall structure of the substrate processing apparatus according to a second embodiment of the invention;

FIG. 11 is a plan view of the substrate processing apparatus which is shown in FIG. 10; and

FIG. 12 is a flow chart which shows an operation of the substrate processing apparatus which is shown in FIG. 10.

### DETAILED DESCRIPTION OF THE PREFERRED EMBODIMENTS

### First Embodiment

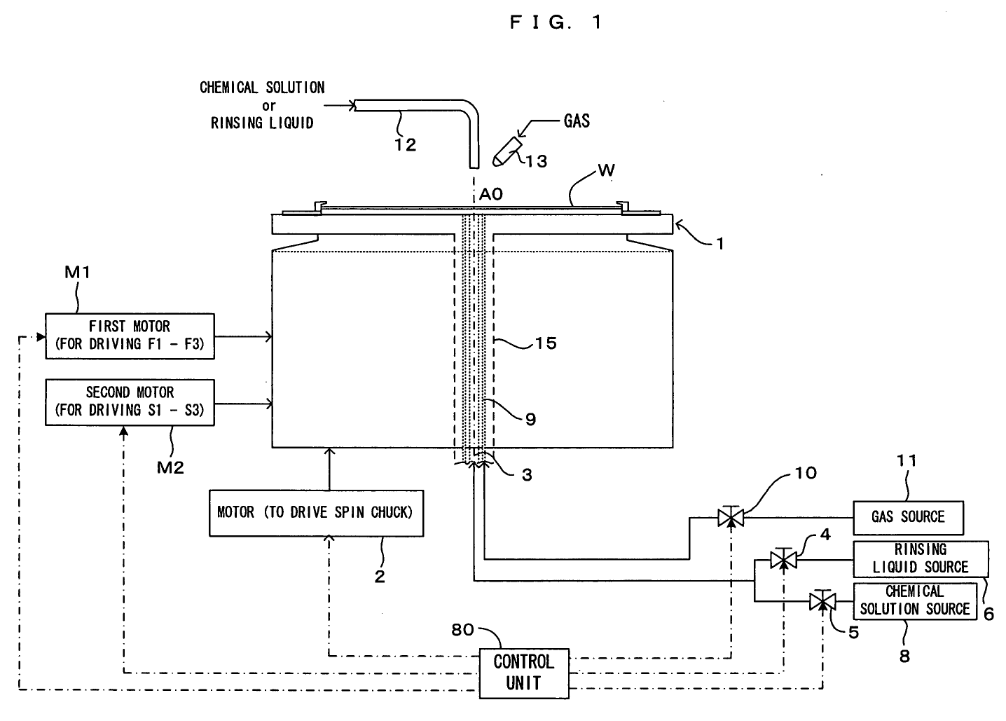

FIG. 1 is a drawing which shows the overall structure of the substrate processing apparatus according to the first embodiment of the invention. This substrate processing apparatus is an apparatus in which a chemical solution of a chemical substance, an organic solvent or the like and a rinsing liquid which may be pure water or DIW (hereinafter referred to as a “processing liquid”) are supplied to a substrate W such as a semiconductor wafer and the substrate W is chemically processed, rinsed or otherwise processed. For example, this substrate processing apparatus is capable of processing the top surface of a substrate W while supplying a processing liquid to the back surface (which is the top surface in this embodiment) of the substrate W, and is also capable of supplying a processing liquid to the top surface of a substrate W and accordingly processing a bottom rim portion of the substrate W (bevel processing) with the processing liquid which circles down to the bottom surface of the substrate W via an edge surface of the substrate W from the top surface of the substrate W.

This substrate processing apparatus comprises a spin chuck 1 which holds a substrate W approximately horizontally such that the substrate W directs its back surface toward above and which rotates about a vertical axis A0 which is aligned approximately with the center of thus held substrate W. Linked with a rotation shaft 15 which is a drive shaft of a motor 2 (which corresponds to the “substrate rotator” of the invention) serving as a rotation drive mechanism, the spin chuck 1 rotates. The rotation shaft 15 is a hollow shaft and penetrated by a processing liquid supply pipe 3 through which pure water or a chemical solution is supplied. To the processing liquid supply pipe 3, a central shaft nozzle (fixed nozzle) is linked which has an ejection outlet at a position close to the center of the bottom surface of the substrate W which is held by the spin chuck 1. At the ejection outlet of the central shaft nozzle, pure water or the chemical solution is supplied toward the bottom surface of the substrate W.

The processing liquid supply pipe 3 is connected with a rinsing liquid source 6 via an on-off valve 4 and with a chemical solution source 8 via an on-off valve 5 so that as a control unit 80 which controls the apparatus as a whole controls the on-off valves 4 and 5, at the ejection outlet, a chemical solution or a rinsing liquid is selectively supplied to the bottom surface of the substrate W.

Further, the gap between the inner wall surface of the rotation shaft 15 and the outer wall surface of the processing liquid supply pipe 3 defines a cylindrical gas supply path 9, and the gas supply path 9 links at its top end with the space below the substrate W. The gas supply path 9 is connected with a gas source 11 via an on-off valve 10, and therefore, as the on-off valve 10 opens and closes under the control of the control unit 80, gas (e.g., inert gas such as clean air and nitrogen) is supplied to the space below the substrate W.

A nozzle 12 is disposed above the spin chuck 1, to supply a processing liquid such as a chemical solution and a rinsing liquid toward the center of the top surface of the substrate W which is held by the spin chuck 1. In addition, to facilitate drying after processing with the processing liquid, there is a nozzle 13 which supplies the gas to the top surface of the substrate W which is held. The nozzle 12 may be a scan nozzle which is capable of reciprocally moving between a position above the substrate W and a position away from above the substrate W, for the purpose of uniformly processing the entire top surface of the substrate W

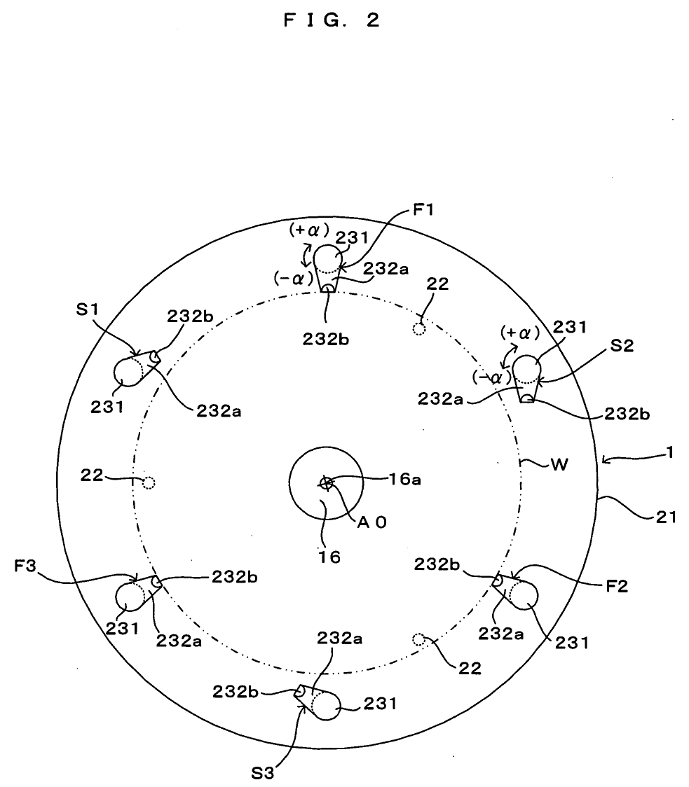

FIG. 2 is a plan view of the spin chuck 1 which is disposed to the substrate processing apparatus which is shown in FIG. 1. The spin chuck 1 comprises a spin base 21 which has a form of circular plate (which corresponds to the “base member” of the invention), and in a rim portion within the top surface of the spin base 21, there are plural (six in this embodiment) chuck pins F1 through F3 and S1 through S3, i.e., the “substrate holders” of the invention, which are apart from each other by approximately equal angles and on the outer side along the diameter direction of the substrate W. The respective chuck pins F1 through F3 and S1 through S3 abut on the outer circumferential edge of the substrate W, pinch the substrate W in the horizontal direction and hold the substrate W. Of these, the three chuck pins F1 through F3 alternately disposed along the circumferential direction belong to a first chuck pin group, and these chuck pins interlock with each other, thereby holding the substrate W or releasing the substrate W. On the other hand, the remaining three chuck pins S1 through S3 belong to a second chuck pin group, and these chuck pins interlock with each other, thereby holding the substrate W or releasing the substrate W.

The chuck pins F1 through F3 forming the first chuck pin group and the chuck pins S1 through S3 forming the second chuck pin group are capable of operating independently of each other. In other words, when the chuck pins F1 through F3 hold the substrate W at edge surface positions which are apart from each other by approximately 120 degrees, the chuck pins S1 through S3 can release the substrate W. Meanwhile, when the chuck pins F1 through F3 have released the substrate W, the chuck pins S1 through S3 can abut on the substrate W at three edge surface positions which are apart from each other by approximately 120 degrees and hold the substrate W. Further, all of the chuck pins F1 through F3 and S1 through S3 may hold the substrate W, in which case the substrate W is held at six edge surface positions which are apart from each other by approximately 60 degrees.

In a rim portion within the top surface of the spin base 21, plural (three in this embodiment) support members 22 are disposed as the “substrate supports” of the present invention which are apart from each other by approximately equal angles and project toward above. Hence, when the support members 22 abut on the bottom surface of the substrate W, the substrate W is supported, as it is floated from the spin base 21, at a position above the spin base 21 (substrate processing position).

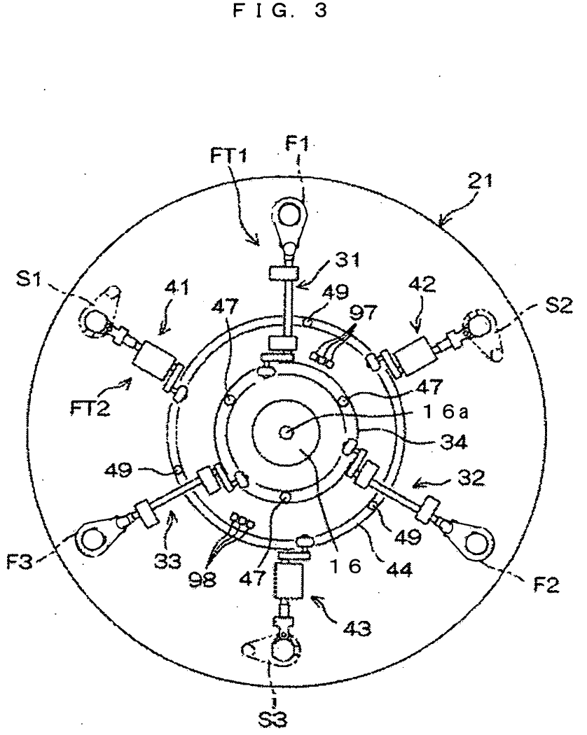

FIG. 3 is a plan view for describing the arrangement of operation translation mechanisms which are disposed inside the spin base 21. Disposed to the spin base 21 are a first operation translation mechanism FT1 which makes the chuck pins F1, F2 and F3 interlock with each other and a second operation translation mechanism FT2 which makes the chuck pins S1, S2 and S3 interlock with each other. The first operation translation mechanism FT1 comprises link mechanisms 31, 32 and 33 which make the chuck pins F1, F2 and F3 interlock with each other and a first interlocker ring 34 which interlocks these link mechanisms 31 through 33. In a similar fashion, the second operation translation mechanism FT2 comprises link mechanisms 41, 42 and 43 which make the chuck pins S1, S2 and S3 interlock with each other and a second interlocker ring 44 which interlocks these link mechanisms 41 through 43.

The first interlocker ring 34 and the second interlocker ring 44 are approximately ring-shaped members which are disposed concentric with respect to the axial line of rotations of the spin base 21, and the second interlocker ring 44 is located on the outer side than the first interlocker ring 34 is. The first and the second interlocker rings 34 and 44 are capable of ascending and descending along the axial line of rotations of the spin base 21. When the first interlocker ring 34 ascends and descends, the chuck pins F1 through F3 operate, whereas when the second interlocker ring 44 ascends and descends, the chuck pins S1 through S3 operate.

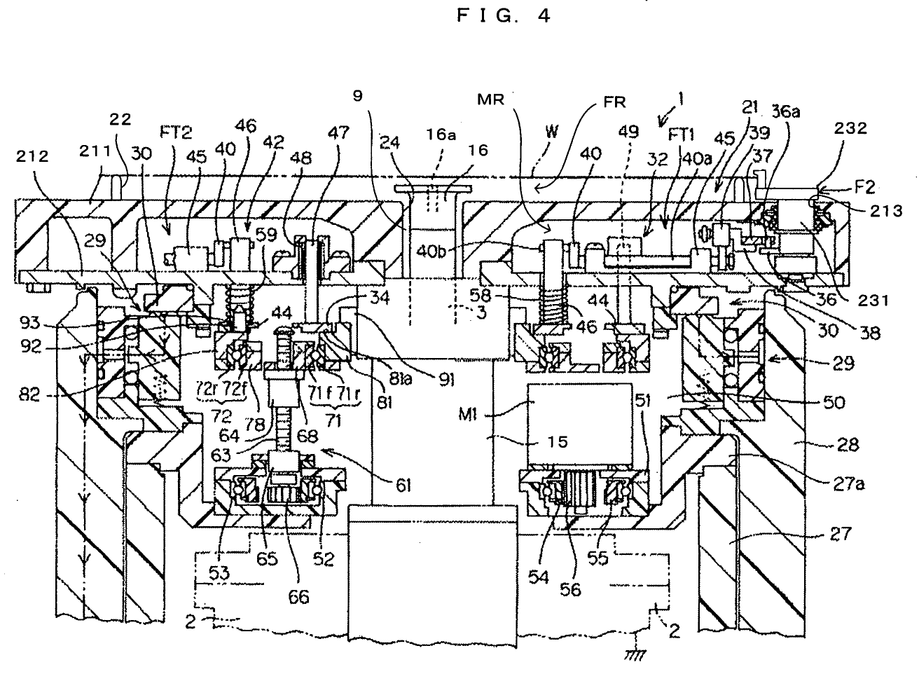

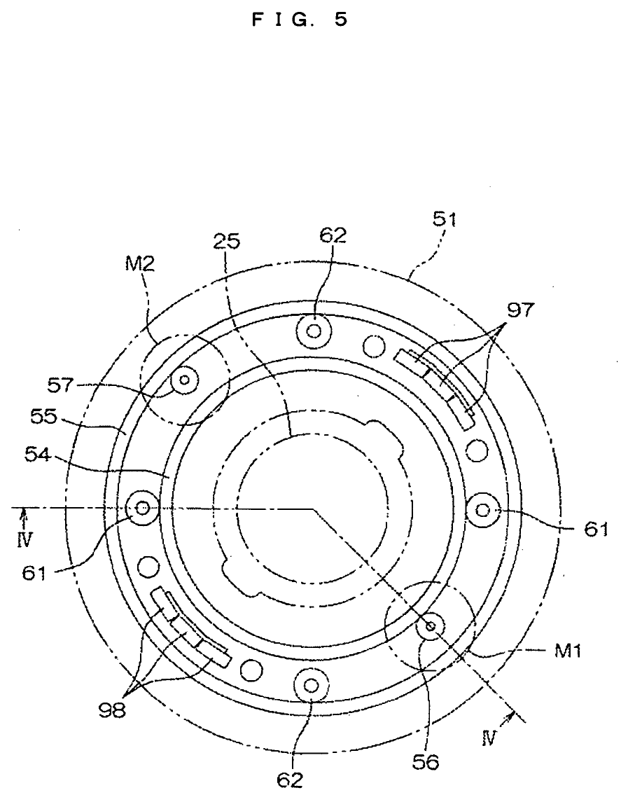

FIG. 4 is a cross sectional view (cross sectional view taken along the IV-IV line in FIG. 5) for describing the structure relevant to the spin chuck 1. The spin base 21 is formed as a top plate 211 and a bottom plate 212 are bolted together, and a rim portion of the top plate 211 comprises through holes 213 in which the chuck pins F1 through F3 and S1 through S3 are disposed such that they can freely move. The through holes 213 are formed on the outer side along the diameter direction of the substrate W relative to an opposed region FR where the spin base 21 is opposed against the substrate W. Hence, the chuck pins F1 through F3 and S1 through S3 as well are located on the outer side along the diameter direction of the substrate W relative to the opposed region FR.

Between the top plate 211 and the bottom plate 212, there is a mechanism space MR in which the first and the second operation translation mechanisms FT1 and FT2 are to be housed. The top plate 211 and the bottom plate 212, at their center, have through holes 24 which penetrate the spin base 21. The processing liquid supply pipe 3 is disposed passing through the through holes 24 and accepting the rotation shaft 15 of the spin chuck 1. To the top end of the processing liquid supply pipe 3, a central shaft nozzle 16 is fixed which comprises an ejection outlet 16a which is opposed against the center of the bottom surface of the substrate W which is held by the spin chuck 1.

The rotation shaft 15 is integrated with the drive shaft of the motor 2 and disposed penetrating the motor 2. There is a casing 27 surrounding the motor 2, and the casing 27 is surrounded further by a cylindrical cover member 28. The top end of the cover member 28 is close even to the bottom surface of the spin base 21, and a seal mechanism 29 is disposed to the inner surface near this top end. The seal mechanism 29 slides against a seal member 30 which is fixed to the bottom surface of the spin base 21, thereby creating between the seal mechanism 29 and the rotation shaft 15 a mechanism housing space 50 which is blocked from an external atmosphere.

Inside the mechanism housing space 50, an approximately ring-shaped gear case 51 surrounding the rotation shaft 15 is attached to a top lid portion 27a of the casing 27. As shown in the plan view in FIG. 5, a first motor M1 and a second motor M2 (which corresponds to the “drive mechanism” of the invention) are fixed on the gear case 51 at symmetric positions with respect to the rotation shaft 15. Bearings 52 and 53 are set under pressure in the gear case 51, respectively on the inner circumferential side and the outer circumferential side of the inner wall surface of the gear case 51 as shown in FIG. 4. The bearings 52 and 53 are disposed coaxial with respect to the rotation shaft 15. A ring-like first gear 54 surrounding the rotation shaft 15 is fixed to a rotation-side ring of the inner bearing 52, whereas a ring-like second gear 55 surrounding the rotation shaft 15 is fixed to a rotation-side ring of the outer bearing 53. Hence, inside the gear case 51, the first gear 54 and the second gear 55 can rotate coaxially with respect to the rotation shaft 15 and the second gear 55 is located on the outer side than the first gear 54 is. The first gear 54 has gear teeth at its outer circumference, and the second gear 55 has gear teeth at its inner circumference.

A pinion 56 fixed to the drive shaft of the first motor M1 comes between the first gear 54 and the second gear 55 and engages with the first gear 54 which is on the inner side. In a similar manner, as shown in FIG. 5, a pinion 57 fixed to the drive shaft of the second motor M2 is located between the first gear 54 and the second gear 55 and engages with the second gear 55 which is on the outer side. Further, on the gear case 51, paired first ball spring mechanisms 61, 61 are disposed at positions avoiding the motors M1, M2 and opposed against each other across the rotation shaft 15 (that is, on the side closer to the rotation shaft 15). Still further, on the gear case 51, other paired second ball spring mechanisms 62, 62 are disposed at positions avoiding the motors M1, M2 and the first ball spring mechanisms 61, 61 and opposed against each other across the rotation shaft 15 (that is, on the side closer to the rotation shaft 15).

The first ball spring mechanisms 61, 61 comprise spring shafts 63 which are parallel to the rotation shaft 15 and ball nuts 64 which engage with the spring shafts 63 as shown in FIG. 4. The spring shafts 63 are attached to a top lid portion of the gear case 51 via bearing portions 65, and the bottom ends of the spring shafts 63 reach even the inside of the gear case 51. Gears 66 are fixed to the bottom ends of the spring shafts 63. The gears 66 come between the first gear 54 and the second gear 55 and engage with the first gear 54 which is disposed on the inner side.

On the other hand, a first non rotation-side movable member 68 is attached to the ball nuts 64. The first non rotation-side movable member 68 is a ring-shaped member surrounding the rotation shaft 15, and non rotation-side rings 71f of first bearings 71 disposed surrounding the rotation shaft 15 are fixed to the inner circumferential surface of the first non rotation-side movable member 68. Rotation-side rings 71r of the first bearings 71 are disposed on the inner side relative to the rotation shaft 15 than the non rotation-side rings 71f are. The rotation-side rings 71r are fixed on the outer circumferential side of a first rotation-side movable member 81 which is ring-shaped and surrounds the rotation shaft 15. The first rotation-side movable member 81 fits with a guide rail 91 which projects from the outer circumferential surface of the rotation shaft 15. The guide rail 91 is formed along a direction which is parallel to the rotation shaft 15 so that guided in a direction along the rotation shaft 15, the first rotation-side movable member 81 is linked with the rotation shaft 15 in such a manner that the first rotation-side movable member 81 can move.

As the first motor M1 drives and the pinion 56 rotates, the rotations are transmitted to the first gear 54. This rotates the gear 66 engaging with the first gear 54, and hence, rotates the spring shafts 63 of the ball spring mechanisms 61, 61. As a result, the ball nuts 64 and the first non rotation-side movable member 68 linked with the ball nuts 64 ascend or descend along the rotation shaft 15. Since the first rotation-side movable member 81 which is supposed to rotate together with the rotation shaft 15 is linked with the first non rotation-side movable member 68 via the bearings 71, as the first non rotation-side movable member 68 ascends or descends, the first rotation-side movable member 81 ascends or descends along the guide rail 91 even when the rotation shaft 15 is still rotating.

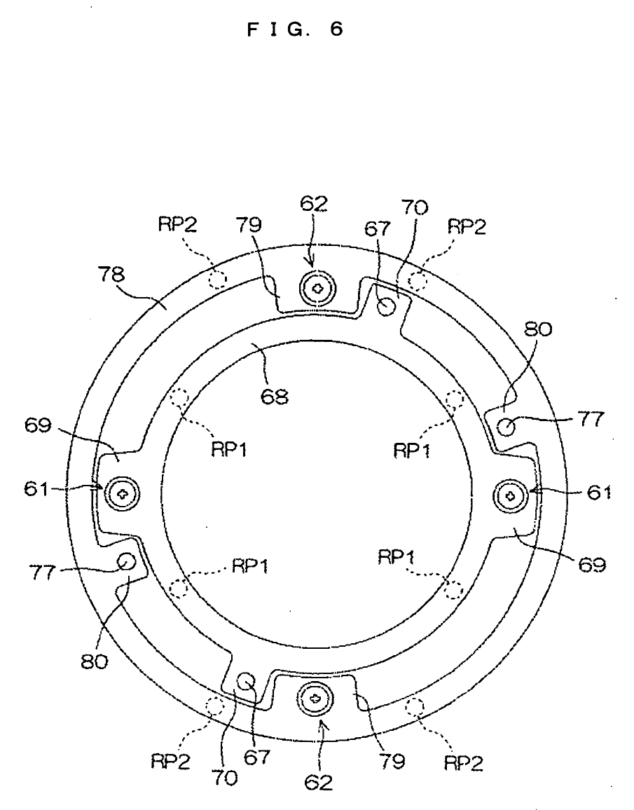

As shown in FIG. 6, other ring-like second non rotation-side movable member 78 is disposed on the outer side relative to the ring-like first non rotation-side movable member 68 which is moved up and down by the first ball spring mechanisms 61, 61. At positions corresponding to the ball nuts 64 of the paired first ball spring mechanisms 61 and 61, paired projections 69, 69 which project outward along the diameter direction are formed in the first non rotation-side movable member 68. Further, at positions deviated from the projections 69, 69 in the circumferential direction, other paired projections 70, 70 are formed. Guide shafts 67, 67 elongated in a direction along the rotation shaft 15 are linked with the paired projections 70, 70. The guide shafts 67, 67 are guided in the vertical direction which is along the rotation shaft 15, allowing that the first non rotation-side movable member 68 ascends or descends along the rotation shaft 15 while posturing itself horizontally.

Meanwhile, the ring-like second non rotation-side movable member 78 comprises paired projections 79, 79 which protrude toward the inner side along the diameter direction, at positions corresponding to the second ball spring mechanisms 62, 62. While the second ball spring mechanisms 62, 62 have similar structures to those of the first ball spring mechanisms 61 described above, a gear disposed at the bottom ends of the spring shafts of the second ball spring mechanisms 62 engages with the second gear 55 from the inner side between the first gear 54 and the second gear 55. Hence, when the second motor M2 drives the pinion 57 similarly engaging with the second gear 55, the ball nuts of the second ball spring mechanisms 62, 62 ascend and descend. The ball nuts are linked with the projections 79, 79 of the second non rotation-side movable member 78.

At positions deviated from the projections 79, 79 in the circumferential direction, other paired projections 80, 80 are formed in the second non rotation-side movable member 78 such that the projections 80, 80 protrude toward the inner side along the diameter direction. Guide shafts 77, 77 are linked respectively with the projections 80, 80. The guide shafts 77, 77 are guided in the vertical direction which is along the rotation shaft 15. Hence, while posturing itself horizontally, the second non rotation-side movable member 78 ascends and descends in the vertical direction which is along the rotation shaft 15.

Fixed to the outer circumferential surface of the second non rotation-side movable member 78 are non rotation-side rings 72f of second bearings 72 which are disposed surrounding the rotation shaft 15, as shown in FIG. 4. Rotation-side rings 72r of the second bearings 72 are fixed to the inner circumferential surface of a ring-like second rotation-side movable member 82 which surrounds the rotation shaft 15. Guide pins 92 projects toward above from the top surface of the second rotation-side movable member 82 in the vertical direction which is along the rotation shaft 15.

When the second non rotation-side movable member 78 ascends or descends together with the nuts of the second ball spring mechanisms 62 and 62, the second rotation-side movable member 82 linked to the same via the second bearings 72 also ascends or descends at the same time. As described later, while the second rotation-side movable member 82 rotates together with the spin base 21 (that is, together with the rotation shaft 15), even when thus rotating, the second rotation-side movable member 82 can ascend and descend owing to the drive force from the second ball spring mechanisms 62.

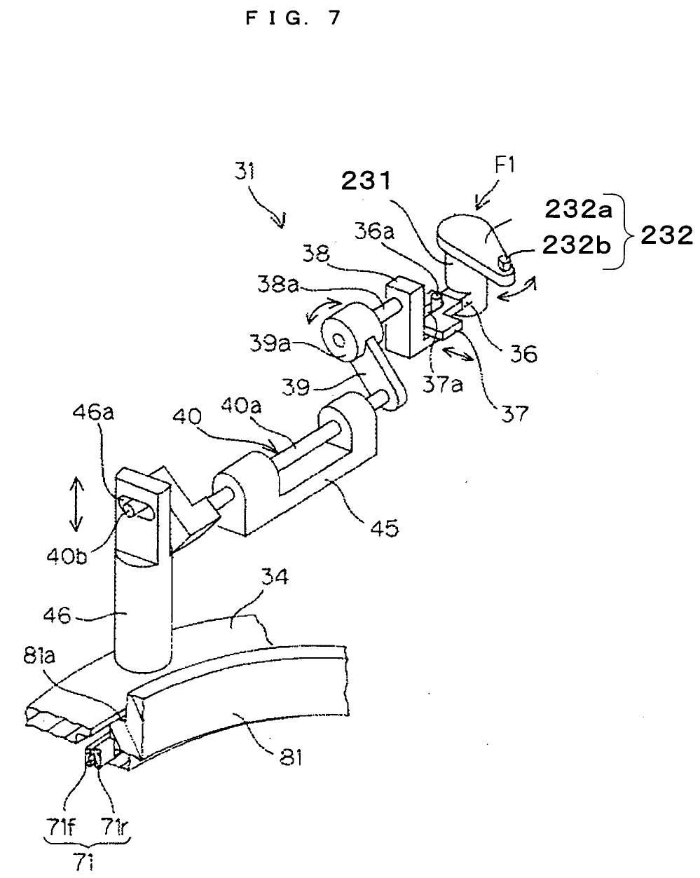

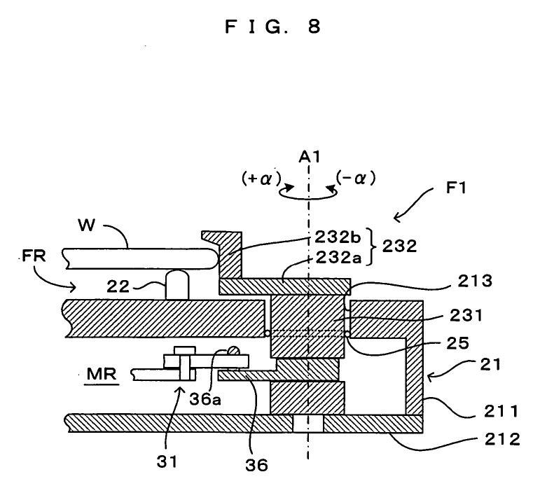

FIG. 7 is a perspective view for describing the structure of the link mechanism 31 which forms the first operation translation mechanism FT1. FIG. 8 is a partial cross sectional view of the structure of the chuck pins. The six chuck pins F1 through F3 and S1 through S3 have the identical structures, and therefore, the structure of one chuck pin F1 will be described. The chuck pin F1 comprises an approximately column-shaped movable main member 231 axially supported at the spin base 21 such that the movable main member 231 can freely revolve about a vertical axis A1 and an abutting member 232 which is fixed on and supported by the movable main member 231. The movable main member 231, disposed penetrating the through hole 213, is capable of revolving and located on the outer side along the diameter direction of the substrate W relative to the opposed region FR.

A lever 36 projecting to the side below the chuck pin F1 is fixed to the movable main member 231, and the tip end of the lever 36 bears a pin 36a which extends vertically toward above. The link mechanism 31 comprises this lever 36, a pivot plate 37 which has a long hole 37a which accepts the lever 36, a crank member 38 linked with the pivot plate 37, a lever 39 which has a bearing portion 39a which axially supports a shaft portion 38a of the crank member 38 in such a manner that the shaft portion 38a can freely rotate, a crank member 40 linked with the lever 39, a bearing portion 45 which supports one shaft portion 40a of the crank member 40 in such a manner that the shaft portion 40a can freely rotate, and an ascend/descend member 46 which has a long hole 46a which accepts the other shaft portion 40b of the crank member 40. The bottom end of the ascend/descend member 46 is linked with the top surface of the first interlocker ring 34. The first interlocker ring 34 is located at such a position at which the first interlocker ring 34 is caught by a shoulder portion 81a which is formed in the outer circumference of the first rotation-side movable member 81.

As shown in FIG. 4, plural (three in this embodiment) guide shafts 47 are disposed on the top surface of the first interlocker ring 34 such that the guide shafts 47 are apart from each other by approximately equal angles and project upright toward above along the rotation shaft 15. The guide shafts 47 penetrate the bottom plate 212 of the spin base 21, and are held by a bush 48 which is disposed in the spin base 21 in such a manner that the guide shafts 47 can ascend and descend. Hence, while posturing itself horizontally, the first interlocker ring 34 ascends and descends together with the first rotation-side movable member 81 along the rotation shaft 15. As the ascend/descend member 46 ascends or descends owing to this, the crank member 40 revolves about the shaft portion 40a which is supported by the bearing portion 45. The long hole 46a formed in the ascend/descend member 46 extends in the horizontal direction, which smoothly translates the ascend/descend motion of the ascend/descend member 46 into revolutions of the crank member 40.

When the crank member 40 revolves, the lever 39 swings and the crank member 38 supported by the bearing portion 39a moves in the plane along the circumferential direction of the spin base 21. Since the long hole 37a formed in the pivot plate 37 is long along the radius direction of the spin base 21 and the pin 36a fits in the long hole 37a in the vertical direction, the pivot plate 37 swings while slightly moving up and down relative to the spin base 21 and while posturing itself horizontally. As the pivot plate 37 thus swings, the pin 36a gets displaced along the circumferential direction of the spin base 21, and therefore, the lever 36 makes the chuck pin F1 revolve via a shaft 35. In this manner, the link mechanism 31 translates the ascend/descend motion of the first rotation-side movable member 81 into revolutions of the chuck pin F1.

Further, as shown in FIG. 8, an extending portion 232a is formed in the abutting member 232, projecting to the side. A holding portion 232b is formed in the tip surface of the extending portion 232a, protruding toward above. Due to this, as shown in FIG. 2, when the movable main member 231 revolves in the clockwise direction (+α) about the vertical axis A1, the holding portion 232b abuts on the outer circumferential edge surface of the substrate W which is supported by the support members 22, and accordingly holds the substrate W. On the contrary, when the movable main member 231 revolves in the anti-clockwise direction (−α) about the vertical axis A1, the holding portion 232b moves away from the outer circumferential edge surface of the substrate W and releases the substrate W. As the holding portion 232b abuts on the outer circumferential edge surface of the substrate W in this manner, the abutting member 232 abuts on the outer circumferential edge surface of the substrate W at a position which is on the inner side along the diameter direction of the substrate W relative to the movable main member 231. In other words, the movable main member 231 is located on the outer side along the diameter direction relative to the position at which the abutting member 232 abuts on the outer circumferential edge surface of the substrate W.

In a boundary portion (movable portion) between the movable main member 231 and the through hole 213 which is formed in the top plate 211 of the spin base 21, for separation of the mechanism space MR from the space leading to above the spin base 21 from the through hole 213, a ring-like seal member 25 is disposed in the movable portion. The seal member 25 is located at the bottom end of the movable portion, that is, in a connecting portion between the mechanism space MR and the through hole 213, thereby preventing the processing liquid from entering the mechanism space MR via the movable portion owing to the capillary phenomenon.

The structures of the link mechanisms 32 and 33 are similar to the structure of the link mechanism 31, and the first interlocker ring 34 makes these link mechanisms operate interlocking with each other. The structures of the link mechanisms 41, 42 and 43 corresponding to the chuck pins S1, S2 and S3 are approximately similar to the structure of the link mechanism 31 and therefore will not be described. However, since the second interlocker ring 44 is located on the outer side along the diameter direction of the spin base 21 than the first interlocker ring 34 is, the shaft portion 40a of the crank member 40 is shorter than in the link mechanism 31, and because of this, the structure of the bearing portion 45 is slightly different. In FIG. 3, denoted at 49 are guide shafts disposed upright in the second interlocker ring 44. The guide shafts 49 have a similar function to that of the guide shafts 47 which are disposed upright in the first interlocker ring 34, and like the guide shafts 47, the guide shafts 49 are linked in such a manner that the guide shafts 49 can ascend and descend relative to the spin base 21.

As shown in FIG. 4, compression coil springs 58 are wound around the ascend/descend members 46 of the link mechanisms 31, 32 and 33 between the bottom surface of a bottom plate 212 of the spin base 21 and the top surface of the first interlocker ring 34. This urges the first interlocker ring 34 toward below, and as a result, the holding portion 232b of the chuck pin F1 is urged in a closing direction which is toward the inner side along the diameter direction of the spin base 21.

Further, as for the link mechanisms 41, 42 and 43 as well, compression coil springs 59 are wound around the ascend/descend members 46 between the bottom surface of the bottom plate 212 of the spin base 21 and the top surface of the second interlocker ring 44. Hence, the holding portions 232b of the chuck pins F1, F2, F3, S1, S2 and S3 are urged in the closing direction which is toward the inner side along the diameter direction of the spin base 21. Therefore, when the ball nuts 64 of the first and the second ball spring mechanisms 61 and 62 are sufficiently below, the chuck pins F1 through F3 and S1 through S3 hold the substrate W because of the spring force of the compression coil springs 58 and 59. This structure flexibly holds the substrate W utilizing the elastic force of the compression coil springs 58 and 59 and hence is advantageous in that the structure is unlikely to damage the substrate W.

For detection of how the chuck pins F1 through F3 and S1 through S3 hold the substrate W, as shown in FIG. 3, there are sensor portions 97 and 98 which respectively detect the height of the first interlocker ring 34 and the height of the second interlocker ring 44. The sensor portions 97 and 98 each comprise three sensors for instance which are arranged so that each detects the first interlocker ring 34 and the second interlocker ring 44 at a first height which corresponds to a state that the holding portions 232b of the chuck pins F1 through F3 and S1 through S3 have retracted from the edge surface of the substrate W, at a second height which corresponds to a state that the chuck pins F1 through F3 and S1 through S3 abut on the edge surface of the substrate W and firmly hold the substrate W, and at a third height at which there is no substrate W on the spin base 21 and the holding portions 232b of the chuck pins F1 through F3 and S1 through S3 are on the inner side along the diameter direction of the spin base 21 than the position of the edge surface of the substrate W is. The first height is the highest followed by the second height, and the third height is the lowest.

It is possible to detect a state that the chuck pins F1 through F3 and S1 through S3 hold the substrate W, a state that the holding is released, and a state that there is no substrate W, based on outputs from the sensor portions 97 and 98. To confirm that the first and the second interlocker rings 34 and 44 ascend and descend together with the ball nuts 64 of the first and the second ball spring mechanisms 61 and 62, another sensor may be disposed which detects the heights of the first and the second non rotation-side movable members 68 and 78.

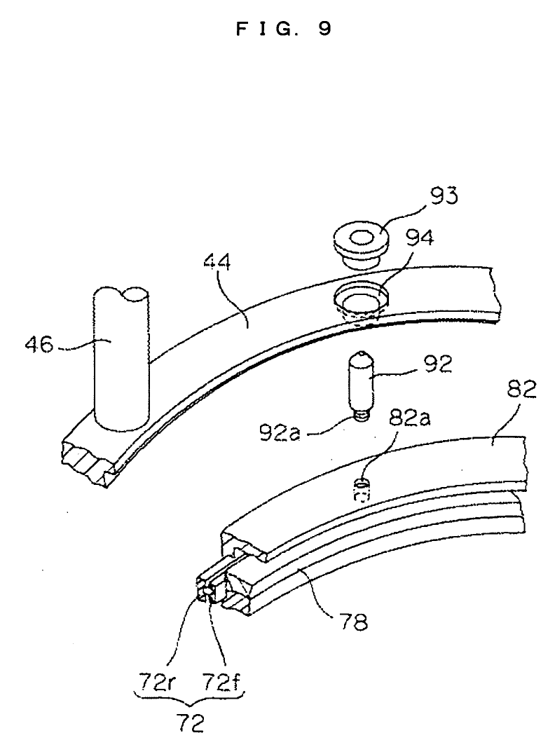

FIG. 9 is an exploded perspective view for describing a structure near link portions between the second interlocker ring 44 and the ascend/descend members 46 of the link mechanisms 41, 42 and 43. There are three ascend/descend members 46, apart from each other by 120 degrees, in the top surface of the second interlocker ring 44. In the top surface of the second interlocker ring 44, stepped through holes 94 are formed apart from each other by 180 degrees and at two positions which are off from the ascend/descend members 46 so that bushes 93 can be fit in the through holes 94. Guide pins 92 which are formed upright in the top surface of the second rotation-side movable member 82 go through the bushes 93. As screw portions 92a at the bottom end of the guide pins 92 engage with screw holes 82a which are formed in the top surface of the second rotation-side movable member 82, the guide pins 92 are fixed to the second rotation-side movable member 82.

The guide pins 92 thus engage with the bushes 93, thereby restricting rotations of the second rotation-side movable member 82 relative to rotations of the second interlocker ring 44 and the ascend/descend members 46 (only those corresponding to the link mechanisms 41, 42 and 43). Hence, as the second ball spring mechanisms 62 make the second non rotation-side movable member 78 ascend or descend, even when the ascend/descend members 46, the second interlocker ring 44 and the second rotation-side movable member 82 are rotating together with the spin base 21, they ascend or descend along the rotation shaft 15 without rotating relative to each other.

In this embodiment, the chuck pins F1 through F3 and S1 through S3 are made of a conductive resin (which may be for example conductive PEEK (polyetheretherketone)) while the respective parts forming the first and the second operation translation mechanisms FT1 and FT2 are made of a conductive resin or metal (such as stainless steel (SUS)). Further, the bottom plate 212 of the spin base 21 is also made of a conductive material (such as SiC and aluminum). Meanwhile, the rotation shaft 15 to which the bottom plate 212 is made of metal such as SUS, and the (metal) casing of the motor 2 is grounded.

This establishes a grounding path leading from the chuck pins F1 through F3 and S1 through S3 to the casing of the motor 2 via the first and the second operation translation mechanisms FT1 and FT2, the bottom plate 212 and the rotation shaft 15. It is therefore possible to discharge static electricity developed by frictions between the substrate W and the processing liquid (a chemical solution and pure water) which is supplied to the surfaces of the substrate W, and therefore, prevent static breakdown of a device which is formed on the substrate W.

Utilizing the drive mechanisms of the chuck pins F1 through F3 and S1 through S3, it is thus possible to eliminate static electricity from the substrate W during spin processing, which makes it unnecessary to separately dispose a static eliminator of the discharge type or the X-ray type and makes it easy to design and reduces a cost. In addition, although a static eliminator of the discharge type causes a problem that metal particles are created and a static eliminator of the X-ray type causes a problem that countermeasures needs be taken to handle radiation, the structure according to this embodiment is free from such problems.

In the substrate processing apparatus having the structure described above, the chuck pins F1 through F3 and S1 through S3 all revolve in the anti-clockwise direction (−α) about the vertical axis A1 and release a substrate. In short, the control unit 80 controls the first and the second motors M1 and M2 so that the first and the second interlocker rings 34 and 44 both come to ascend positions (the first height described above). As a result, each one of the chuck pins F1 through F3 and S1 through S3 becomes the open state that the holding portion 232b of the abutting member 232 has retracted to the outer side along the diameter direction relative to the spin base 21. In this state, a substrate transportation mechanism such as a transportation arm not shown transports an unprocessed substrate W with the non-processing surface (device-seating surface) of the substrate W directed toward below, and places the substrate W on the support members 22.

Controlling the first motor M1 for instance, the control unit 80 drives the first ball spring mechanisms 61 and makes the ball nuts 64 descend. Since this moves down the first rotation-side movable member 81, the first interlocker ring 34 descends, and the ascend/descend members 46 move down subjected to the spring force from the compression coil springs 58 and gravity. In consequence, the chuck pins F1 through F3 revolve in the clockwise direction (+α) about the vertical axis A1, and their holding portions 232b abut on the outer circumferential surface of the substrate W. The chuck pins F1 through F3 accordingly hold the substrate W. At this stage, since the second motor M2 is not driven, the chuck pins S1 through S3 are in the open state (namely, the state that the holding portions 232b have retracted from the edge surface of the substrate W). While particles may be created as the movable main members 231 slide relative to the spin base 21 when the chuck pins F1 through F3 revolve, since the movable main members 231 are located on the outer side along the diameter direction of the substrate W relative to the opposed region FR, adhesion of the particles to the substrate W is reduced. This is similar as for revolutions of the chuck pins S1 through S3 which will be described later.

Next, the control unit 80 activates the motor 2, thereby rotating the rotation shaft 15 about the vertical axis A0 and hence the substrate W thus held rotates about the vertical axis A0. To the top surface of the substrate W in this condition, a chemical solution is supplied as the processing liquid from the nozzle 12. The chemical solution supplied to the top surface of the substrate W spreads out due to the centrifugal force owing to rotations of the substrate W, and the back surface (non-device seating surface) of the substrate W is accordingly processed. Further, a part of the chemical solution supplied to the top surface of the substrate W circles down over to the bottom surface (device-seating surface) of the substrate W via the edge surface of the substrate W, and a bottom rim portion of the substrate W is accordingly processed. The amount of the chemical solution circles down in this manner is restricted by the gas which is ejected toward a central portion in the bottom surface of the substrate W and further to the opposed region FR from the gas supply path 9.

During processing with the chemical solution, the control unit 80 drives an electric motor M2 and hence moves the second interlocker ring 44 toward below while keeping the spin chuck 1 rotating. In other words, the ball nuts 64 of the ball spring mechanisms 62 descend, which moves down the second interlocker ring 44 due to the spring force from the compression coil springs 59 and gravity. Since this also moves down the ascend/descend members 46 (corresponding to the link mechanisms 41, 42 and 43), the chuck pins S1 through S3, being acted upon by the second operation translation mechanism FT2, revolve in the clockwise direction (+α). The holding portions 232a of the chuck pins S1 through S3 then abut on the outer circumferential surface of the substrate W, and the chuck pins S1 through S3 thus hold the substrate W. Since the chuck pins F1 through F3 is still holding the substrate W at this stage, the substrate W is held at all of the six chuck pins F1 through F3 and S1 through S3.

The control unit 80 then controls the electric motor M1 in addition, while keeping the spin chuck 1 rotating. In short, the ball nuts 64 of the ball spring mechanisms 61 ascend and the first interlocker ring 34 accordingly ascends against the spring force from the compression coil springs 58. As a result, the chuck pins F1 through F3, being acted upon by the first operation translation mechanism FT1, revolve in the anti-clockwise direction (−α), and the holding portions 232a of the chuck pins F1 through F3 retract from the outer circumferential surface of the substrate W. Holding with the chuck pins F1 through F3 is released in this manner. Hence, after this, the substrate W keeps rotating while being held at the chuck pins S1 through S3. In this fashion, it is possible to thoroughly process the rim portion and the edge surface of the substrate W without stopping the rotations of the spin chuck 1.

While supply of the processing liquid from the nozzle 12 is stopped as a predetermined period of processing time elapses, the substrate W keeps rotating, whereby the substrate W is drained off of the chemical solution adhering to the same. Upon draining of the chemical solution, the control unit 80 supplies the rinsing liquid to the top surface of the substrate W from the nozzle 12, to thereby perform rinsing in a similar manner to that for chemical processing described above. The chemical solution adhering to the substrate W is thus substituted with the rinsing liquid and gets washed off. During this rinsing with pure water as well, when the chuck pins F1 through F3 and the chuck pins S1 through S3 switch with each other to hold the substrate W in a similar manner to the above, all surfaces of the substrate W are uniformly and favorably rinsed. Even if there already is some chemical solution in the boundary portion (movable portion) between the movable main members 231 and the spin base 21, since the movable main members 231 are on the outer side along the diameter direction of the substrate W relative to the opposed region FR, more rinsing liquid is supplied than where the movable main members 231 are disposed within the opposed region FR. This achieves quicker substitution with the rinsing liquid and shortens the rinsing time.

After rinsing for a predetermined period of time, the control unit 80 stops supply of the rinsing liquid from the nozzle 12, and the substrate is drained off of the rinsing liquid and dried. As the gas is supplied at the nozzle 13 from the gas supply path 9 during drying, drying is facilitated.

While the processing liquid such as the chemical solution entered the movable portion during processing with the chemical solution or the rinsing liquid or at the stage of drying of the substrate W could float up as vapor toward above the spin base 21, partly because of the locations of the movable main members 231 on the outer side along the diameter direction of the substrate W relative to the opposed region FR and partly because of the effect by the supplied gas and the centrifugal force, the processing liquid is prevented from adhering to the substrate W. To be noted in particular, it is possible to avoid corrosion of the non-processing surface (device-seating surface) because of adhesion of the processing liquid to the non-processing surface. As adhesion of the processing liquid to the substrate W is prevented, it is possible to perform uniform processing such as etching.

After drying for a predetermined period of time, the control unit 80 stops supply of the gas at the nozzle 13 from the gas supply path 9, whereby the motor 2 stops operating and the substrate W stops rotating. Further, all chuck pins F1 through F3 and S1 through S3 revolve in the anti-clockwise direction (−α) about the vertical axis A1. In consequence, the holding portions 232b of the holding portions 232 retract from the outer circumferential surface of the substrate W and the substrate is released. The substrate W thus released is then transported outside by the substrate transportation mechanism such as a transportation arm not shown.

As described above, in this embodiment, since the movable main members 231 of the chuck pins F1 through F3 and S1 through S3 are disposed on the outer side along the diameter direction of the substrate W relative to the opposed region FR, even with the processing liquid such as the chemical solution entering the boundary portion (movable portion) between the movable main members 231 and the spin base 21, the processing liquid in the movable portion is prevented from adhering as vapor to the substrate W during drying or processing with the processing liquid of the substrate W. Hence, it is possible to avoid corrosion of the bottom surface (non-processing surface) because of adhesion of the processing liquid to the non-processing surface of the substrate W. This ensures uniform processing such as etching with the chemical solution. In addition, since the movable main members 231 are on the outer side along the diameter direction of the substrate W relative to the opposed region FR, even when particles are created as the movable main members 231 slide against the spin base 21, adhesion of the particles to the substrate W is reduced.

Further, in this embodiment, since the multiple support members 22 which abut on the bottom surface of the substrate W and support the substrate W are disposed on the spin base 21, it is possible to avoid damaging, contamination and the like of the bottom surface of the substrate which will otherwise occur when the substrate W is mounted on the spin base 21. Since the multiple support members 22 are fixed on the spin base 21, there is no gap between the support members 22 and the spin base 21 and hence no room for the processing liquid to intrude. This eliminates inconveniences due to entry of the processing liquid to the movable portion.

In addition, in this embodiment, since the movable main members 231 are disposed on the outer side along the diameter direction of the substrate W relative to the opposed region FR, the rinsing liquid flows out toward the outer side along the diameter direction of the substrate W as the substrate W rotates and more rinsing liquid is supplied to the movable portion as compared with where the movable main members 231 are disposed within the opposed region. Substitution with the rinsing liquid therefore proceeds quickly, shortening the rinsing time.

### Second Embodiment

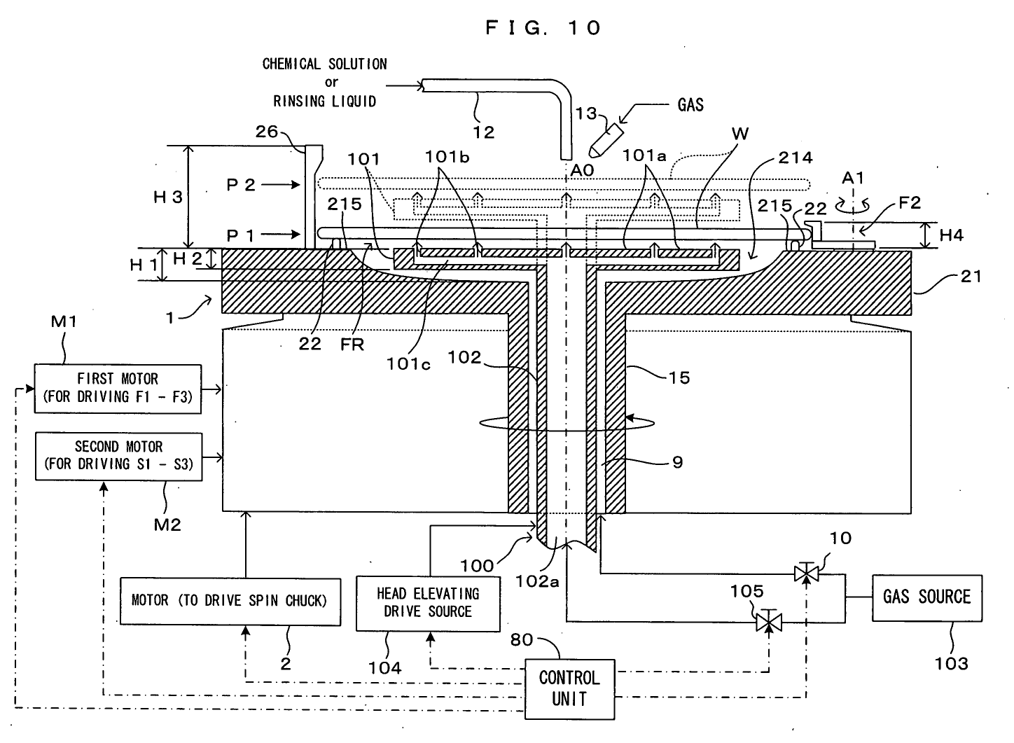

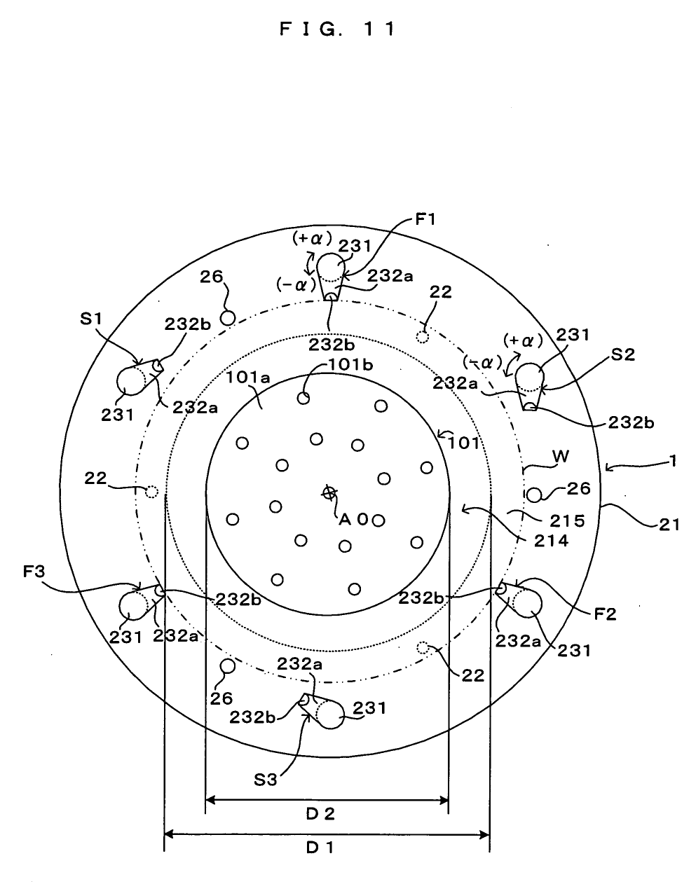

FIG. 10 is a drawing which shows the overall structure of the substrate processing apparatus according to the second embodiment of the invention, and FIG. 11 is a plan view of the substrate processing apparatus which is shown in FIG. 10. A major difference of the second embodiment from the first embodiment is that a substrate elevating mechanism 100 is newly disposed. As a substrate W is placed close to the spin base 21, it is not possible to insert the substrate transportation mechanism such as a transportation arm into between the substrate W and the spin base 21. Noting this, this embodiment requires disposing the substrate elevating mechanism 100 and transporting a substrate in the following manner, and hence, it is possible to arrange the substrate W and the spin base 21 close to each other while permitting transportation of the substrate with a transportation arm or the like.

The substrate elevating mechanism 100 comprises a substrate floating head 101, a head supporting arm 102, a gas supplying unit 103, and an the head elevating drive source 104. The gas is ejected from a front portion of the substrate floating head 101 toward the bottom surface of the substrate W, whereby the substrate W is levitated approximately horizontally. The head supporting arm 102 is hollow and cylindrical and is attached to a rear portion of the substrate floating head 101 and supports the head. The gas supplying unit 103 is communicated with the hollow section of the head supporting arm 102 and is capable of supplying the gas to the substrate floating head 101 via the head supporting arm 102. The head elevating drive source 104, such as a pneumatic cylinder and the like, moves the substrate floating head 101 and the head supporting arm 102 along the up and down direction as one integrated unit.

The substrate floating head 101 is at its central portion of the bottom portion fixed to a top end of the head supporting arm 102 as one integrated unit and is supported horizontally by the head supporting arm 102. The head supporting arm 102 is disposed penetrating the hollow section of the rotation shaft 15 coaxially with the vertical axis A0 and is structured to ascend and descend freely. The head supporting arm 102 is linked with the head elevating drive source 104, and therefore, when a control unit 80 which controls the whole of the apparatus drives the head elevating drive source 104, the substrate floating head 101 and the head supporting arm 102 ascend and descend as one integrated unit. In this manner, the head supporting arm 102 is disposed instead of the processing liquid supply pipe 3 in the hollow portion of the rotation shaft 15 in this embodiment.

The substrate floating head 101 has a shape like a disk which is smaller than the plane size of the substrate W, and its top surface 101a is disposed opposing the bottom surface of the substrate W. There are plural gas ejection outlets 101b formed in the top surface 101a of the substrate floating head 101 so that it is possible to eject gas up along an approximately vertical direction toward the bottom surface of the substrate W. As the gas is thus supplied into the space which is created between the bottom surface of the substrate W and the top surface 101a, the substrate W floats up. When these gas ejection outlets 101b are disposed about the vertical axis A0 so as to be equidistant from each other along the circumference which is at any desired diameter on the top surface 101a as shown in FIG. 11 for instance or disposed coaxially in addition to that, it is possible to float up the substrate W approximately horizontally above the top surface 101a. To the extent that the gas is ejected toward the bottom surface of the substrate W and the substrate W floats up approximately horizontally, the number and the arrangement of the gas ejection outlets may be determined freely.

Each one of the plural gas ejection outlets 101b formed in the top surface 101a of the substrate floating head 101 links to a gas distributing space 101c which is created inside the substrate floating head 101. Further, a gas supply path 102a is provided inside the head supporting arm 102 axially along the vertical axis A0, and the top end of the gas supply path 102a links to the gas distributing space 101c. Meanwhile, the bottom end of the gas supply path 102a is connected with the gas source 103 via an on-off valve 105.

The structure of the spin base 21 will now be described in detail with reference to FIGS. 10 and 11. The spin base 21 is provided with a dent 214 which is concave toward the inner side and whose plane form is circular in a central portion of a top surface. The dent 214 is formed on the spin base 21 such that its plane size D1 is larger than the plane size D2 of the substrate floating head 101 and that its depth H1 in the up-down direction exceeds the height H2 of the substrate floating head 101. Hence, when the substrate floating head 101 moves down, the substrate floating head 101 retracts into the dent 214. That is, the top surface 101a of the substrate floating head 101 is below the plane of the top surface 215 of the spin base 21. Further, the top surface 215 in a form of a ring surrounding the dent 214 serves as a substrate opposing surface 215 which is opposed against the bottom surface of the substrate W. This opposing surface 215 is positioned parallel and facing the bottom surface of the substrate W at a predetermined distance from the bottom surface of the substrate W when the substrate W descends. Further, in this embodiment, at the entire circumference of the opposing surface 215, there are multiple (three in this embodiment) support members 22 fixedly disposed apart from each other by approximately equal angles and project upright toward above (FIG. 11), and as the support members 22 abut on the bottom surface of the substrate W, the substrate W is supported at a position (substrate processing position P1) which is off by a predetermined distance from the spin base 21 (opposing surface 215) toward above.

To restrict the substrate W from moving in the horizontal direction, multiple (three in this embodiment) guide pins 26 are disposed upright at the rim of the substrate W above the spin base 21. While the substrate W which has been transported by the substrate transportation mechanism such as a transportation arm at a substrate transfer position P2 which is above the substrate processing position P1 is being positioned at the substrate processing position P1 or while the substrate W which has been positioned at the substrate processing position P1 is being positioned at the substrate transfer position P2 for transfer to the substrate transportation mechanism, the guide pins 26 restrict movements of the substrate W at horizontal positions and prevent the substrate W from flying out in the horizontal direction. The substrate transfer position P2 is a position spaced toward above from the spin base 21 to such an extent that a transportation arm or the like can be inserted between the bottom surface of the substrate W and the spin base 21 for transfer of the substrate W to and from the transportation arm or the like. To this end, the height H3 of the guide pins 26 in the up-down direction is higher than the height of at least the substrate transportation mechanism such as the transportation arm. On the contrary, with respect to the chuck pins F1 through F3 and S1 through S3, it is not necessary to consider the condition at the time of transportation of a substrate such as the height of the substrate transportation mechanism such as the transportation arm: the chuck pins are designed in light only of holding of the substrate positioned at the substrate processing position P1. The height H4 of the abutting members 232 of the chuck pins F1 through F3 and S1 through S3 is set about the same as or slightly higher than the thickness of the substrate W but lower than the height H3 of the guide pins 26. This reduces the centrifugal force which acts upon the abutting members 232 when the abutting members 232 rotate. In this manner, in this embodiment, the guide pins 26 are disposed separately from the chuck pins F1 through F3 and S1 through S3 which function as the substrate holders, and the guide pins 26 function as the “restrictor” of the invention.

The other structure, including a feature that the chuck pins F1 through F3 and S1 through S3 are located on the outer side along the diameter direction of the substrate W relative to the opposed region FR, is basically similar to that of the first embodiment, and therefore, the identical structure will be denoted at corresponding reference symbols but will not be described.

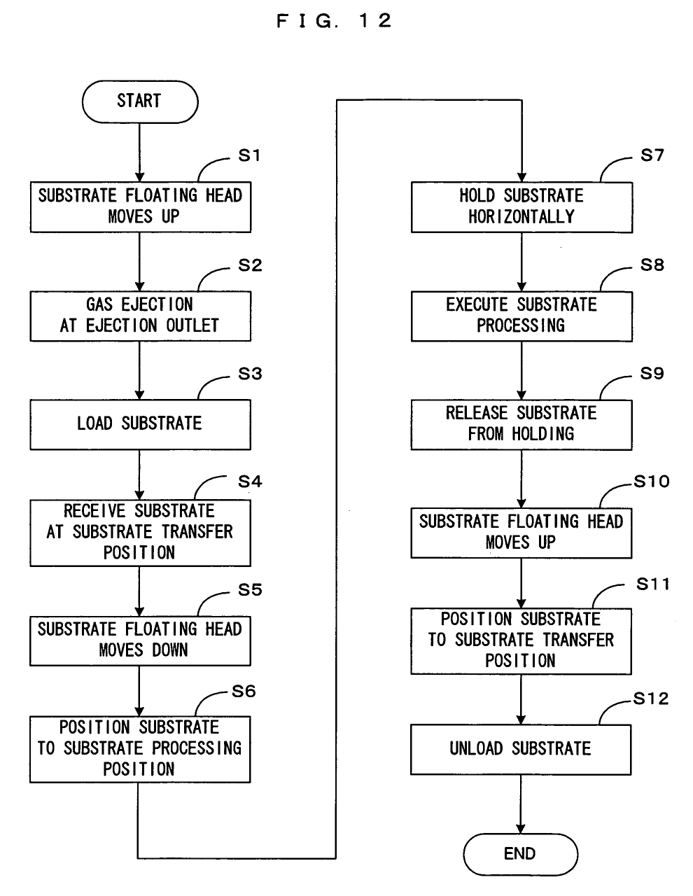

An operation of a substrate W in the substrate processing apparatus having the structure above will now be described with reference to FIG. 12. FIG. 12 is a flow chart which shows an operation of the substrate processing system which is shown in FIG. 10. First, the control unit 80 makes the head elevating drive source 104 ascend, thereby moving the substrate floating head 101 and the head supporting arm 102 upward as one unit (Step 1). When the top surface 101a of the substrate floating head 101 stops after ascending to immediately below the substrate transfer position P2 which is spaced toward above from the spin base 21, the control unit 80 opens the on-off valve 105 and the gas is ejected up at the gas ejection outlets 101b of the substrate floating head 101 (Step S2). As the substrate W is thus transported to the substrate transfer position P2, the substrate floating head 101 can now receive the substrate W. The control unit 80 may make the substrate floating head 101 ascend after the gas has been ejected at the gas ejection outlets 101b and while ejection of the gas continues, or alternatively, at the same time that the gas is ejected.

Following this, the substrate transportation mechanism such as the transportation arm loads an unprocessed substrate W with the non-processing surface (device-seating surface) of the substrate W directed toward below into inside the apparatus, and as the substrate W reaches the substrate transfer position P2 (Step S3), the gas ejected from the substrate floating head 101 which is located at the bottom surface of the substrate W floats up the unprocessed substrate W. The transportation arm gets pulled away from the unprocessed substrate W or otherwise retracts, and the unprocessed substrate W is handed to the substrate floating head 101 (Step S4). As a result, the unprocessed substrate W is supported at the substrate floating head 101 without contacting anywhere, due to the gas ejected toward the bottom surface of the substrate W and supplied into the space which is created between the bottom surface of the substrate W and the top surface 101a of the substrate floating head 101. The guide pins 26 disposed at the rim of the spin base 21 restrict the unprocessed substrate W from moving in the horizontal direction.

Next, the control unit 80 makes the head elevating drive source 104 descend while the substrate floating head 101 floats up the unprocessed substrate W approximately horizontally, the unprocessed substrate W moves down (Step S5). Since the unprocessed substrate W descends while restricted by the guide pins 26 as for movements in the horizontal direction, the substrate W is guided smoothly toward the substrate processing position P1 without flying sideways in the horizontal direction from the substrate floating head 101. When the unprocessed substrate W reaches the substrate processing position P1, the bottom rim portion of the substrate W engages with the support members 22, and further, as the substrate floating head 101 descends, the unprocessed substrate W is transferred to and mounted on the support members 22. The substrate W is positioned at the substrate processing position P1 in this fashion, and the bottom rim portion of the substrate W and the opposing surface 215 of the spin base 21 are arranged close to and facing with each other (Step S6).

The substrate floating head 101 keeps descending and the entire substrate floating head 101 retracts into the dent 214 of the spin base 21. After this, the control unit 80 closes the on-off valve 105, thereby stopping ejection of the gas from the substrate floating head 101. Alternatively, the control unit 80 may maintain ejection of the gas from the substrate floating head 101, in addition to supply of the gas from the gas supply path 9 which will be described later, instead of stopping ejection of the gas.

With respect to the unprocessed substrate W mounted on the support members 22, as the three chuck pins F1 through F3 revolve in the clockwise direction (+α) about the vertical axis A1, the holding portions 232b of the abutting members 232 abut on the outer circumferential surface of the substrate W and the substrate W is held firmly in the horizontal direction (Step S7). Following this, in a similar procedure to that in the first embodiment, the top surface of the substrate W and/or the rim portion in the bottom surface (device-seating surface) of the substrate W are subjected to predetermined processing (Step S8). In other words, during processing with the processing liquid, the three chuck pins S1 through S3 in addition revolve in the clockwise direction (+α) while the spin chuck 1 keeps rotating, the substrate W is held at all of the six chuck pins F1 through F3 and S1 through S3. After the three chuck pins F1 through F3 have revolved in the anti-clockwise direction (−α) and released the substrate, the substrate W keeps rotating while being held at the three chuck pins S1 through S3. During processing, the control unit 80 may open the on-off valve 10, making it possible to supply the gas into the entire space which is created between the bottom surface of the substrate W and the top surface of the spin base 21 from the gas supply path 9 via the space which is created between the bottom surface of the substrate floating head 101 and the bottom surface of the dent 214. This restricts the amount of the processing liquid which circles down to the bottom rim portion of the substrate W.

Thus processed substrate W is unloaded in the reverse order to that for loading of an unprocessed substrate W. After predetermined processing of the substrate W, all chuck pins F1 through F3 and S1 through S3 revolve in the anti-clockwise direction (−α) about the vertical axis A1, and the holding portions 232b of the holding portions 232 retract from the outer circumferential surface of the substrate W and the substrate W is released (Step S9). The control unit 80 thereafter moves up the head elevating drive source 104, which causes the substrate floating head 101 which has retracted into the dent 214 to ascend while ejecting the gas at the gas ejection outlets 101b (Step S10). In this manner, the gas ejected at the gas ejection outlets 101b floats up the processed substrate W approximately horizontally. As the processed substrate W moves up to the substrate transfer position P2, driving of the head elevating drive source 104 is stopped and the substrate W is accordingly positioned (Step S11). The substrate transportation mechanism such as the transportation arm then unloads the processed substrate W to outside the apparatus (Step S12).

As described above, in this embodiment, since the movable main members 231 of the chuck pins F1 through F3 and S1 through S3 are disposed on the outer side along the diameter direction of the substrate W relative to the opposed region FR, similar effects to those according to the first embodiment are obtained. The second embodiment additionally promises the following unique effects. That is, separately from the abutting members 232, the second embodiment uses the guide pins 26 which restrict horizontal movements of the substrate W which ascends and descends between the substrate processing position P1 and the substrate transfer position P2. This arrangement is free from a restriction imposed by the condition at the time of transportation of a substrate, e.g., a restriction that the height H4 of the abutting members 232 along the up-down direction must be higher than the height of the substrate transportation mechanism for insertion of the substrate transportation mechanism such as the transportation arm below the bottom surface of the substrate. The height H4 of the abutting members 232 along the up-down direction is set lower than the height H3 of the guide pins 26, which reduces the centrifugal force which acts upon the abutting members 232 when the abutting members 232 rotate. This attains to the following effects.

In short, when the abutting members 232 are under strong centrifugal force, the movable main members 231 supporting the abutting members 232 shift toward the outer side along the diameter direction of the substrate W, widening the gap in the boundary portion (movable portion) between the movable main members 231 on the inner side along the diameter direction of the substrate and the spin base 21 and making it easy for the processing liquid to enter the movable portion. Further, shifting of the movable main members 231 reduces the air-tightness realized by the seal member 25 which is disposed at the bottom end of the movable portion for separation of the mechanism space MR from the space expanding from the through holes 213 toward above the spin base 21 (or sometimes even destroys the seal member 25), permitting the processing liquid adhere to the mechanical portions of the drive mechanisms such as the link mechanisms 31 through 33, 41 through 43 and the like which are located below the movable portion, thereby the processing liquid corrode the mechanical portions (FIG. 8).

On the contrary, in this embodiment, since the centrifugal force which acts upon the abutting members 232 is reduced, it is possible to suppress entry of the processing liquid to the movable portion. Further, since shifting of the movable main members 231 is reduced, it is possible to decrease the influence over the air-tightness realized by the seal member 25 and prevent the processing liquid from corroding the mechanical portions of the drive mechanisms such as the link mechanisms 31 through 33, 41 through 43 and the like. Still further, reduced shifting of the movable main members 231 weakens sliding of the movable main members 231 against the spin base 21 and suppresses creation of particles. Meanwhile, the height H4 of the guide pins 26 along the up-down direction is under a restriction associated with the condition at the time of transfer of the substrate, e.g., a restriction that the height H4 must be higher than the height of the substrate transportation mechanism, and is accordingly subjected to centrifugal force corresponding to this height. However, since the guide pins 26 have no movable sections, no inconveniences attributable to entry of the processing liquid to the movable portion is expected.

Further, in this embodiment, as the substrate floating head 101 ascends or descends, the substrate W moves to and is positioned at, as it is supported at the substrate floating head 101 without contacting the same, the substrate processing position P1 and to the substrate transfer position P2 which is above the substrate processing position P1. Since the substrate W is thus transferred at the substrate transfer position P2 which is above the substrate processing position P1, the substrate processing position P1 is free from any restriction because of the condition at the time of transfer of the substrate W, e.g., that the height the substrate transportation mechanism such as the transportation arm along the up-down direction, which permits positioning the substrate W at any desired substrate processing position. Hence, the substrate processing position can be a position at which the spin base 21 (opposing surface 215) and the substrate W come sufficiently close to each other. As the substrate W and the spin base 21 are brought close to each other in this manner, the height H4 of the abutting members 232 of the chuck pins F1 through F3 and S1 through S3 can be further lowered. This even more effectively suppresses entry of the processing liquid to the movable portion and creation of particles.

### Others

The invention is not limited to the embodiments described above but may be modified in various fashions other than those described above to the extent not deviating from the intention of the invention. For instance, although all chuck pins F1 through F3 and S1 through S3 serving as the substrate holders are movable substrate holders in the embodiments described above, as long as at least one chuck pin is movable, as for this movable substrate holder, it is possible to prevent inconveniences attributable to entry of the processing liquid to the movable portion of this movable substrate holder. Meanwhile, as for the fixed substrate holders, since they have no movable portions, no inconveniences attributable to entry of the processing liquid to movable portions is expected.

Further, although the six chuck pins F1 through F3 and S1 through S3 are disposed apart from each other by approximately equal angles in the top rim portion of the spin base 21 in the embodiments described above, as long as the movable main members 231 of the chuck pins are disposed on the outer side along the diameter direction of a substrate W relative to the opposed region FR where the spin base 21 is opposed against the substrate W, the number and the arrangement of the chuck pins may be determined freely.

With respect to the support members 22 which serve as the substrate supports as well, to the extent that they support a substrate W approximately horizontally, the number and the arrangement of the support members may be determined freely. For instance, as for the arrangement of the support members 22, the support members 22 may be disposed on the normal lines (i.e., lines from the center of the substrate W to the positions at which the abutting members 232 abut on the outer circumferential surface of the substrate W) located at the positions at which the abutting members 232 abut on the outer circumferential surface of the substrate W, to thereby support the substrate W.

Further, although the second embodiment described above requires that as the substrate floating head 101 ascends or descends, the substrate W is positioned at the substrate processing position P1 and to the substrate transfer position P2, the spin base 21 may ascend or descend while the substrate floating head 101 remains fixed to thereby position the substrate W. Alternatively, both the substrate floating head 101 and the spin base 21 may ascend and descend for positioning of the substrate W.

In addition, while the second embodiment described above requires ejecting the gas up along an approximately vertical direction toward the bottom surface of a substrate W from the substrate floating head 101, the gas may be ejected upward yet toward the rim of the substrate W. With the gas ejected toward the bottom surface of the substrate W from the substrate floating head 101 in this manner, owing to the Bernoulli's effect, it is possible to float up the substrate W while sucking the substrate W toward the top surface of the substrate floating head 101. Due to this, even when the outer circumferential surface of the substrate W gets caught by the guide pins 26 during positioning of the substrate W while restricting the substrate W from moving in the horizontal direction by means of the guide pins 26, the suction force acting upon the substrate W toward the substrate floating head 101 makes it possible to stably move the substrate W toward above or below, as it is held approximately horizontally, together with the substrate floating head 101 as one integrated unit.

Further, although the spin chuck 1 rotates and the substrate W accordingly rotates in the embodiments described above, the invention is not limited only to such an application. For instance, the invention is applicable also to where a processing liquid is supplied to a substrate W while maintaining the substrate W still or moving the substrate W in predetermined one direction. To be noted, the invention is applicable generally to any substrate processing apparatus which abuts on an outer circumferential surface of a substrate W thereby holding the substrate W, supplies a processing liquid to the substrate W, and performs predetermined processing.

Although the invention has been described with reference to specific embodiments, this description is not meant to be construed in a limiting sense. Various modifications of the disclosed embodiment, as well as other embodiments of the present invention, will become apparent to persons skilled in the art upon reference to the description of the invention. It is therefore contemplated that the appended claims will cover any such modifications or embodiments as fall within the true scope of the invention.

What is claimed is:

1. A substrate processing apparatus which performs predetermined processing by supplying a processing liquid to a substrate which is held at a substrate processing position, comprising:
plural substrate holders each of which includes an abutting member which is capable of abutting on an outer circumferential surface of said substrate, and which hold said substrate by contacting said abutting members with said outer circumferential surface of said substrate at said substrate processing position; and
a base member which seats said plural substrate holders,
wherein at least one of said plural substrate holders are movable substrate holders, and said movable substrate holders comprise movable main members which are structured to freely move relative to said base member with supporting said abutting members, and a drive mechanism which drives said movable main members and accordingly makes said abutting members abut on and move away from said outer circumferential surface of said substrate, and
said movable main members are disposed on the outer side along the diameter direction of said substrate relative to an opposed region where said base member is opposed against said substrate.

2. The substrate processing apparatus of claim 1, further comprising plural substrate supports which are fixed on said base member, abut on the bottom surface of said substrate, and support said substrate at a distance from said base member.

3. The substrate processing apparatus of claim 1, wherein said abutting members of said movable substrate holders abut on said outer circumferential surface of said substrate at positions which are on the inner side along the diameter direction of said substrate relative to said movable main members.

4. The substrate processing apparatus of claim 1, further comprising a restrictor which restricts movements of said substrate in the horizontal direction when said substrate ascends or descends relative to said base member between said substrate processing position and a substrate transfer position which is above said substrate processing position,
wherein the height of each one of said abutting members along the up-down direction is lower than the height of said restrictor.

5. The substrate processing apparatus of claim 1, further comprising a substrate rotator which rotates said base member and thereby rotates said substrate which is held by said plural substrate holders,
wherein a rinsing liquid is supplied to thus rotating substrate and rinsing is accordingly performed as said predetermined processing.
